(19) United States
(12) Patent Application Publication
(10) Pub. No.: US 2010/0327354 A1
(43) Pub. Date: Dec. 30, 2010

(54) THIN FILM TRANSISTOR HAVING LONG LIGHTLY DOPED DRAIN ON SOI SUBSTRATE AND PROCESS FOR MAKING SAME

(75) Inventors: Jin Jang, Seoul (KR); Carlo Anthony Kosik Williams, Painted Post, NY (US); ChuanChe Wang, Horsheads, NY (US)

Correspondence Address: Bruce P Watson;Corning Incorporated, SP-TI-3-1, Corning, NY, 14831, US

(73) Assignee: CORNING INCORPORATED/ KYUNG HEE UNIVERSITY

(21) Appl. No.: 12/865,006

(22) PCT Filed: Jan. 27, 2009
(86) PCT No.: PCT/US09/00533

§ 371 Date: Jul. 28, 2010

Related U.S. Application Data
(60) Provisional application No. 61/063,076, filed on Jan. 31, 2008.

(51) Int. Cl. H01L 29/786; H01L 21/336

(52) U.S. Cl. 257/347; 438/163; 257/E29.295; 257/E21.415

(57) ABSTRACT

Methods and apparatus for producing a thin film transistor (TFT) result in: a glass or glass ceramic substrate; a single crystal semiconductor layer; a source structure disposed on the single crystal semiconductor layer; a drain structure disposed on the single crystal semiconductor layer; and a gate structure located with respect to the drain structure defining a lightly doped drain region therein, wherein a lateral length of the lightly doped drain region is such that the TFT exhibits a relatively low carrier mobility and moderate sub-threshold slope suitable for OLED display applications.

### CROSS REFERENCE TO RELATED APPLICATIONS

This application claims the benefit of U.S. Provisional Patent Application No. 61/063,076, filed Jan. 31, 2008, the entire disclosure of which is hereby incorporated by reference.

### BACKGROUND

The present invention relates to the manufacture of thin film transistors (TFTs) on a semiconductor-on-insulator (SOI) structure using improved processes and techniques, for example, for organic light emitting diodes and arrays.

Organic light emitting diodes (OLEDs) have been the subject of a considerable amount of research in recent years because of their use and potential use in a wide variety of electroluminescent devices. For instance, a single OLED can be used in a discrete light emitting device or an array of OLEDs can be used in lighting applications or flat-panel display applications (e.g., active matrix OLED displays). Traditional OLED displays are known to be very bright, to have a good color contrast, to produce true color, and to exhibit a wide viewing angle.

Thin film transistors (TFTs) are used in a variety of electronic applications, including OLEDs, liquid crystal displays (LCDs), photovoltaic devices, integrated circuits, etc.

With reference to FIG. 1, in LCD applications, e.g., for the mobile display industry, a TFT 10 may be employed as a primary transistor in an LCD array. The TFT 10 is a field effect transistor (FET) having a low temperature polysilicon (LTPS) substrate 12, and a semiconductor region 13 on or part of the substrate 12. Disposed on the semiconductor region 13 are a gate structure 14 on an oxide layer 15, a drain contact structure 16, and a source contact structure 18. Respective portions between the gate structure 14 and each of the drain contact structure 16 and the source contact structure 18 define respective lightly doped drain (LDD) portions 20 and corresponding LDD lengths (L₁ & L₂). The region under the gate oxide 15 and between the LDD regions 20 is the channel 17 of the TFT 10.

As is well known in the art, an LDD is a region of reduced doping and reduced doping gradient between the drain and the channel in a relatively small geometry MOS/CMOS transistor. Given the symmetry of a FET, the characteristics of the LDD (usually defined in terms of the structure of the drain) is also applicable to the source. The LDD is intended, in accordance with conventional thinking, to control drain-to-substrate breakdown. The reduced doping gradient is intended to lower the electric field in the channel in the vicinity of the drain. The LDD also reduces the leakage current and improves reliability of the TFT 10. In accordance with known processes, an LDD may be implemented using a moderate implant procedure before spacer formation of the drain region followed by a relatively heavy implant after the spacer formation. The length of the LDD region of such TFTs is normally in the range of about 1-2 μm for an optimized Ion/Ioff ratio.

With reference to FIG. 2, in the LCD application the optimum Ion/Ioff ratio for a specific TFT employing LTPS and LDD technology (which for discussion purposes may be considered typical) occurs at an LDD length of about 1 um. In addition, the LDD length of about 1-2 um has an effect on the sub-threshold slope (SS), which is the slope of the current (drain-to-source) through the TFT as a function of the gate-to-source voltage, and the carrier mobility through the channel. Indeed, relatively short LDD lengths of about 1-2 um in TFTs using LTPS technology result in steep SS (rapid changes in current as a function of gate-to-source voltage) and high carrier mobility—ideal characteristics for LCD applications.

While the LDD length of about 1-2 um provides advantages in the LCD application discussed above, a TFT used in a current controlled OLED application is required to have moderate SS (relatively moderate changes in current as a function of gate-to-source voltage) and low carrier mobility—virtually opposite to the ideal characteristics of the LCD application. Thus, using a conventional TFT employing LTPS and LDD technology in an OLED application is problematic. This problem is exacerbated when the TFTs are fabricated on a semiconductor on insulator (SOI) substrate, such as a single crystal silicon on glass (SiOG) substrate. Indeed, when a TFT is fabricated on a single crystal silicon on glass (SiOG) substrate, an extremely steep SS and very high mobility is the norm. Thus, what would otherwise be considered a high performance TFT is not ideal for use in driving OLED devices.

### SUMMARY

In accordance with one or more embodiments of the present invention, methods and apparatus of forming a TFT, result in: a glass or glass ceramic substrate; a single crystal semiconductor layer; a source structure disposed on the single crystal semiconductor layer; a drain structure disposed on the single crystal semiconductor layer; and a gate structure located with respect to the drain structure defining a lightly doped drain region therein. A lateral length of the lightly doped drain region is such that the TFT exhibits a relatively low carrier mobility and moderate sub-threshold slope suitable for OLED display applications. Indeed, lengthening the LDD region results in uniform degradation of the SS and mobility to a relatively moderate SS and low carrier mobility.

For a single crystal semiconductor layer of silicon, and the TFT of p-type, the carrier mobility may be less than about 10 cm²/V·s. For example, the carrier mobility may be about 6 cm²/V·s. The sub-threshold slope may be at least about 600 mV/dec, such as about 700-900 mV/dec. It should be noted that the p-type TFT is desired for driving the OLED device because it intrinsically has a lower on-state current and lower carrier mobility than the n-type TFT. Although the p-type TFT is desired, the n-type TFT can also be used, where a greater carrier mobility reduction is needed. For a single crystal semiconductor layer of silicon, and a TFT of n-type, the carrier mobility may be less than about 10 cm²/V·s, such as about 6 cm²/V·s. The sub-threshold slope may be at least about 600 mV/dec, such as about 700-900 mV/dec.

As to physical measurements, a lateral length of the lightly doped drain region may be greater than about 4 um. For example, the lateral length of the lightly doped drain region may be about 5 um.

In alternative configurations, the single crystal semiconductor layer may be taken from the group consisting of: silicon (Si), germanium-doped silicon (SiGe), silicon carbide (SiC), germanium (Ge), gallium arsenide (GaAs), GaP, and InP.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1 is a block diagram illustrating the structure of a thin film transistor (TFT) formed on a polysilicon substrate in accordance with the prior art;

FIG. 2 is a graph illustrating the relationship between the on-current and off-current of a typical TFT formed on a polysilicon substrate and employing a lightly doped drain;

FIG. 3 is a block diagram illustrating the structure of a thin film transistor (TFT) formed on an SOG substrate in accordance with one or more embodiments of the present invention;

FIG. 4 is a graph illustrating the relationship between the drain-to-source current as a function of the gate-to-source voltage of a TFT employing a lightly doped drain; and

FIGS. 5-7 are graphs illustrating the relationships between various currents and voltages of the TFT of FIG. 3.

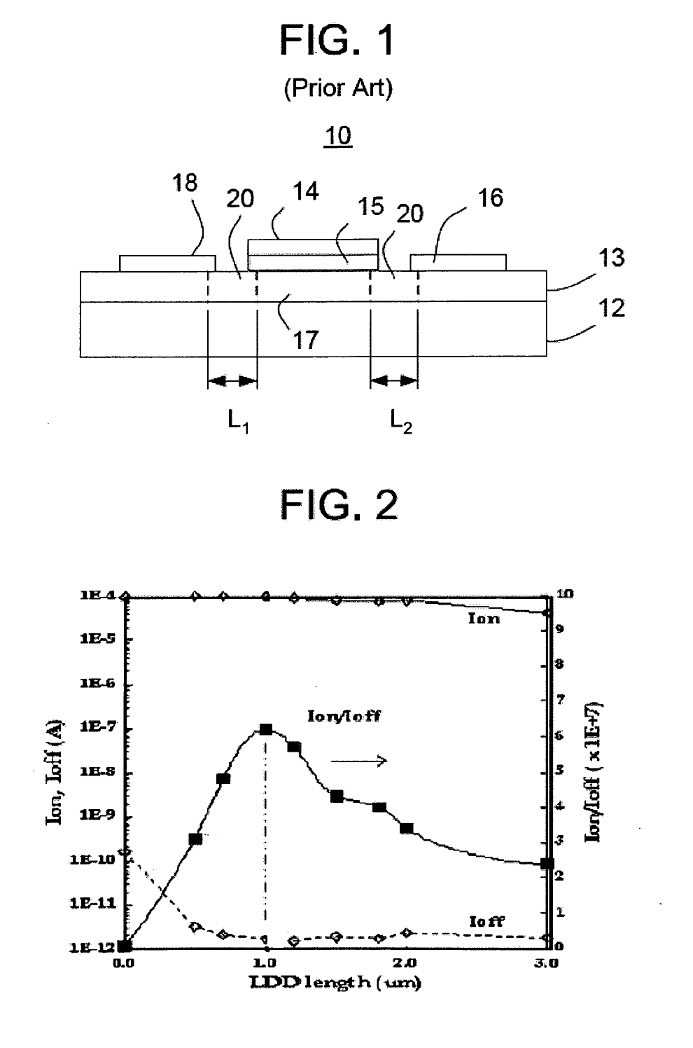

### DETAILED DESCRIPTION

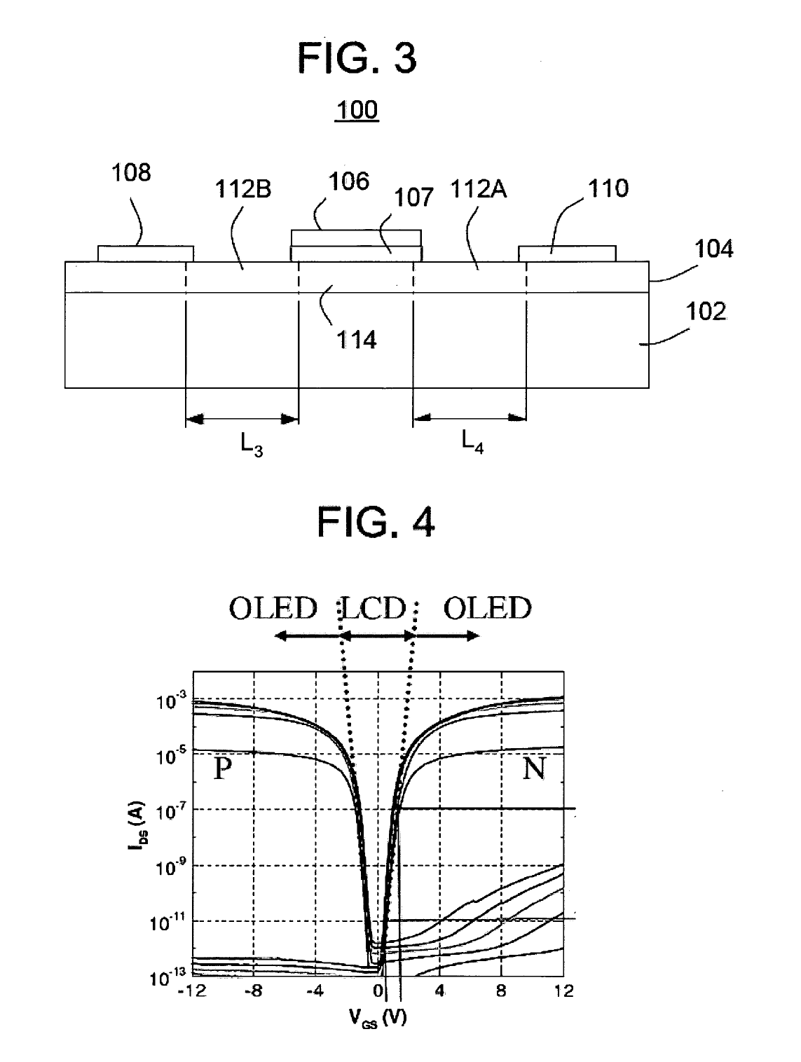

With reference to the drawings, wherein like numerals indicate like elements, there is shown in FIG. 3 a thin film transistor, TFT 100 formed on a SOG structure in accordance with one or more embodiments of the present invention. The TFT 100 has application for use in displays, preferably organic light-emitting diode (OLED) displays. The TFT 100 includes a glass or glass ceramic substrate 102, and a semiconductor layer 104. Disposed on the semiconductor layer 104 of the TFT 100 are: a gate contact (or simply “gate”) 106 over an oxide layer 107, a source contact (source) 108, and a drain contact (drain) 110. Respective portions between the gate 106 and each of the drain 110 and the source 108 define respective lightly doped drain (LDD) portions 112A, 112B and corresponding LDD lengths (L₃ & L₄). The region of the semiconductor layer 104 under the gate oxide 107 and between the LDD regions 112A, 112B is the channel 114 of the TFT 100. As will be discussed further herein, the LDD length is of importance in determining the electrical performance of the TFT 100.

The semiconductor material of the layer 104 may be in the form of a substantially single-crystal material on the order of about 10-200 nm thick. The term “substantially” is used in describing the layer 104 to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material.

For the purposes of discussion, it is assumed that the semiconductor layer 104 is formed from silicon. It is understood, however, that the semiconductor material may be a silicon-based semiconductor or any other type of semiconductor, such as, the III-V, II-IV, II-IV-V, etc. classes of semiconductors. Examples of these materials include: silicon (Si), germanium-doped silicon (SiGe), silicon carbide (SiC), germanium (Ge), gallium arsenide (GaAs), GaP, and InP.

The glass substrate 102 may be formed from an oxide glass or an oxide glass-ceramic in the range of about 0.1 mm to about 10 mm, such as in the range of about 0.5 mm to about mm. By way of example, the glass substrate 102 may be formed from glass substrates containing alkaline-earth ions and may be silica-based, such as, substrates made of CORNING INCORPORATED GLASS COMPOSITION NO. 1737 or CORNING INCORPORATED GLASS COMPOSITION NO. EAGLE 2000®. These glass materials have particular use in, for example, the production of displays. The glass or glass-ceramic substrate 102 may be designed to match a coefficient of thermal expansion (CTE) of one or more semiconductor materials (e.g., silicon, germanium, etc.) of the layer 104 that are bonded together. The CTE match ensures desirable mechanical properties during heating cycles of the deposition process.

The single crystal semiconductor layer 104 may be bonded to the glass substrate 102 using any of the existing techniques. Among the suitable techniques is bonding using an electrolysis process. A suitable electrolysis bonding process is described in U.S. Pat. No. 7,176,528, the entire disclosure of which is hereby incorporated by reference. Portions of this process are discussed below. In the bonding process, a semiconductor donor wafer (e.g., a single crystal silicon wafer) is subject to ion implantation, such as hydrogen and/or helium ion implantation, to create a zone of weakness below a bonding surface of the donor wafer. The glass substrate 102 and the bonding surface of the donor semiconductor wafer are brought into direct or indirect contact and are heated under a differential temperature gradient. Mechanical pressure is applied to the intermediate assembly (e.g., about 1 to about 50 psi.) and the structure is taken to a temperature within about +/−150 degrees C. of the strain point of the glass substrate 102. A voltage is applied with the donor semiconductor wafer at a positive potential and the glass substrate 102 a negative potential. The intermediate assembly is held under the above conditions for some time (e.g., approximately 1 hour or less), the voltage is removed and the intermediate assembly is allowed to cool to room temperature.

As some point during the above process, the donor semiconductor wafer and the glass substrate 102 are separated, to obtain a glass substrate 102 with a relatively thin exfoliation layer of the semiconductor material bonded thereto. The separation of the donor semiconductor wafer from the exfoliation layer that is bonded to the glass substrate 102 is accomplished through application of stress to the zone of weakness within the donor semiconductor wafer, such as by a heating and/or cooling process. It is noted that the characteristics of the heating and/or cooling process may be established as a function of a strain point of the glass substrate 102. Although the invention is not limited by any particular theory of operation, it is believed that glass substrates 102 with relatively low strain points may facilitate separation when the respective temperatures of the donor semiconductor wafer and the glass substrate 102 are falling or have fallen during cooling. Similarly, it is believed that glass substrates 102 with relatively high strain points may facilitate separation when the respective temperatures of the donor semiconductor wafer and the glass substrate 102 are rising or have risen during heating. Separation of the donor semiconductor wafer and the glass substrate 102 may also occur when the respective temperatures thereof are neither substantially rising nor falling (e.g., at some steady state or dwell situation).

The application of the electrolysis bonding process causes alkali or alkaline earth ions in the glass substrate 102 to move away from the semiconductor/glass interface further into the glass substrate 102. More particularly, positive ions of the glass substrate 102, including substantially all modifier positive ions, migrate away from the higher voltage potential of the semiconductor/glass interface, forming: (1) a reduced positive ion concentration layer in the glass substrate 102 adjacent the semiconductor/glass interface; and (2) an enhanced positive ion concentration layer of the glass substrate 102 adjacent the reduced positive ion concentration layer. This accomplishes a number of features: (i) an alkali or alkaline earth ion free interface (or layer) is created in the glass substrate 102; (ii) an alkali or alkaline earth ion enhanced interface (or layer) is created in the glass substrate 102; (iii) an oxide layer is created between the exfoliation layer and the glass substrate 102; and (iv) the glass substrate 102 becomes very reactive and bonds to the exfoliation layer strongly with the application of heat at relatively low temperatures. Additionally, relative degrees to which the modifier positive ions are absent from the reduced positive ion concentration layer in the glass substrate 102, and the modifier positive ions exist in the enhanced positive ion concentration layer are such that substantially no ion re-migration from the glass substrate 102 into the exfoliation layer (and thus into any of the structures later formed thereon of therein).

The cleaved surface of the SOI structure just after exfoliation may exhibit excessive surface roughness, excessive semiconductor layer 104 thickness, and implantation damage of the semiconductor layer 104 (e.g., due to the formation of a damaged semiconductor layer). Post processing is carried out to achieve a desired thickness of the semiconductor layer 104, such as a thickness of about 10-200 nm.

The SOG structure described above is further processed to form the TFT 100 using known procedures. For example, the semiconductor layer 104 may be subject to patterned oxide and metal deposition procedures (e.g., etching techniques) and doping using ion shower techniques (and or any of the other known techniques). Finally, inter-layers, contact holes, and metal contacts may be disposed using known fabrication techniques to produce the TFT 100 of FIG. 3. The above fabrication procedures are adapted to result in an LDD length of greater than about 4 um (which is about twice a long as the prior art TFT structures for LCD applications). Experiments have indicated that an LDD length of about 5 um results in desirable performance characteristics for OLED display applications.

A TFT used in a current controlled OLED application should have moderate SS (relatively moderate changes in current as a function of gate-to-source voltage) and low carrier mobility. Such characteristics do not naturally result using typical TFT fabrication techniques on single crystal SOI substrates used in LCD applications. Indeed, as illustrated in FIG. 4, when a TFT is fabricated on a single crystal silicon on glass (SiOG) substrate, an extremely steep SS and very high mobility is the norm. Thus, what would otherwise be considered a high performance TFT (mobility >150 cm²/Vs and SS <250 mV/dec for p-type TFT) is not ideal for use in driving OLED devices.

Lengthening the LDD region 112 to greater than about 4 um results in uniform degradation of the SS and mobility to a relatively moderate SS and low carrier mobility. In the context of the present invention it is noted that there are inherent differences in the SS and carrier mobility of a p-type FET as compared with an n-type FET, the former having more moderate SS and lower carrier mobility than the latter. Thus, a skilled artisan will appreciate from the description herein that a p-type FET may be a more desirable structure in which to apply the various aspects of the present invention, for example the longer LDD region, since more moderate SS and lower carrier mobility are design goals. It is understood, however, that the features of the present invention may also be applied to an n-type FET even though such FETs start with inherently steeper SS and higher carrier mobility than p-type FETs. For example, when the TFT is of a p-type, the LDD length may be formed such that the carrier mobility is less than about 10 cm²/V·s, such as about 4-10 cm²/V·s, more particularly about 6 cm²/V·s, and the sub-threshold slope is at least about 600 mV/dec, more particularly about 700-900 mV/dec. When the TFT is of an n-type, the LDD length may be formed such that the carrier mobility is less than about 10 cm²/V·s, such as about 4-10 cm²/V·s, more particularly about 6 cm²/V·s, and the sub-threshold slope is at least about 600 mV/dec, more particularly about 700-900 mV/dec.

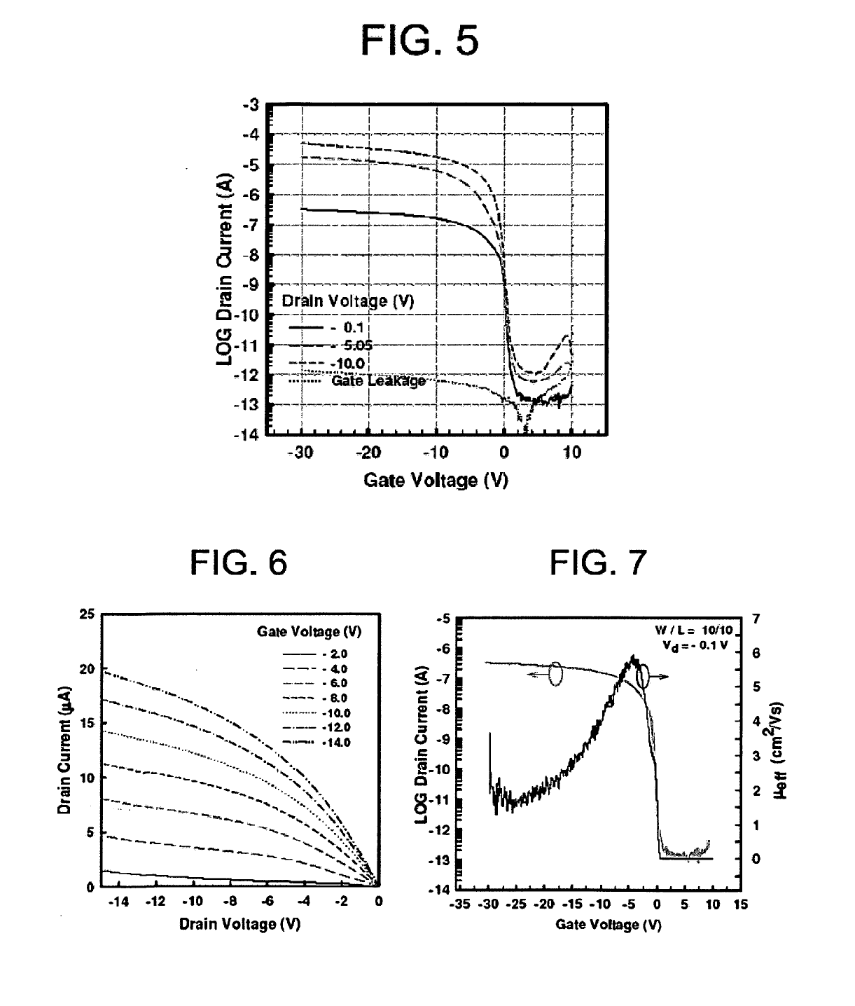

While the LDD length of about 1-2 um provides advantages in the LCD application, a TFT used in a current controlled OLED application is required to have moderate SS (relatively moderate changes in current as a function of gate-to-source voltage) and low carrier mobility—virtually opposite to the ideal characteristics of the LCD application. Thus, using a conventional TFT employing LTPS and LDD technology in an OLED application is problematic. With reference to FIGS. 5-7, graphs are provided showing the relationships between various currents and voltages of a p-type TFT 100 on a single crystal silicon layer 104 and glass substrate 102 having an LDD length of about 5 um. The graphs reveal that the resulting SS is about 740 mV/dec and carrier mobility is about 5.9 cm²/V·s. These are satisfactory parameters for an active matrix OLED display. Indeed, lengthening the LDD region 112 to greater than about 4 um results in uniform degradation of the SS and mobility to a relatively moderate SS and low carrier mobility.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A thin film transistor (TFT), comprising:
a glass or glass ceramic substrate;
a single crystal semiconductor layer;
a source structure disposed on the single crystal semiconductor layer;
a drain structure disposed on the single crystal semiconductor layer; and
a gate structure located with respect to the drain structure defining a lightly doped drain region therein,
wherein a lateral length of the lightly doped drain region is of sufficient length such that the TFT exhibits a carrier mobility of less than about 10 cm²/V·s and a sub-threshold slope of at least about 600 mV/dec.

2. The thin film transistor of claim 1, wherein the lateral length of the lightly doped drain region is of sufficient length such that the TFT exhibits a carrier mobility of less than about 6 cm²/V·s.

3. The thin film transistor of claim 1, wherein the lateral length of the lightly doped drain region is of sufficient length such that the TFT exhibits a sub-threshold slope of about 700-900 mV/dec.

4. The thin film transistor of claim 1, wherein the lateral length of the lightly doped drain region is greater than about 4 um.

5. The thin film transistor of claim 4, wherein the lateral length of the lightly doped drain region is about 5 um.

6. The thin film transistor of claim 1, wherein:
the single crystal semiconductor layer is silicon; and
the TFT is one of p-type and n-type.

7. The thin film transistor of claim 1, wherein the single crystal semiconductor layer is taken from the group consisting of: silicon (Si), germanium-doped silicon (SiGe), silicon carbide (SiC), germanium (Ge), gallium arsenide (GaAs), GaP, and InP.

8. The thin film transistor of claim 1, wherein the glass or glass ceramic substrate includes:
a first layer adjacent to the single crystal semiconductor layer with a reduced positive ion concentration having substantially no modifier positive ions; and
a second layer adjacent to the first layer with an enhanced positive ion concentration of modifier positive ions, including at least one alkaline earth modifier ion from the first layer.

9. The thin film transistor of claim 1, wherein the glass or glass ceramic substrate includes:
a first layer adjacent to the single crystal semiconductor layer with a reduced positive ion concentration having substantially no modifier positive ions;
a second layer adjacent to the first layer with an enhanced positive ion concentration of modifier positive ions; and
relative degrees to which the modifier positive ions are absent from the first layer and the modifier positive ions exist in the second layer are such that substantially no ion re-migration from the glass or glass ceramic substrate into the single crystal semiconductor layer may occur.

10. A thin film transistor (TFT), comprising:
a glass or glass ceramic substrate;
a single crystal semiconductor layer;
a source structure disposed on the single crystal semiconductor layer;
a drain structure disposed on the single crystal semiconductor layer; and
a gate structure located with respect to the drain structure defining a lightly doped drain region therein,
wherein a lateral length of the lightly doped drain region is greater than about 4 um.

11. The thin film transistor of claim 12, wherein the lateral length of the lightly doped drain region is about 5 um.

12. A method of forming a thin film transistor (TFT), comprising:
bonding a single crystal semiconductor layer a glass or glass-ceramic substrate;
forming a source structure on the single crystal semiconductor layer;
forming a drain structure on the single crystal semiconductor layer; and
forming a gate structure located with respect to the drain structure and defining a lightly doped drain region therein, wherein a lateral length of the lightly doped drain region is of sufficient length such that the TFT exhibits a carrier mobility of less than about 10 cm²/V·s and a sub-threshold slope of at least about 600 mV/dec.

13. The method of claim 12, wherein the lateral length of the lightly doped drain region is of sufficient length such that the TFT exhibits a carrier mobility of less than about 6 cm²/V·s.

14. The method of claim 12, wherein the lateral length of the lightly doped drain region is of sufficient length such that the TFT exhibits a sub-threshold slope of about 700-900 mV/dec.

15. The method of claim 1, wherein the lateral length of the lightly doped drain region is greater than about 4 um.

16. The method of claim 15, wherein the lateral length of the lightly doped drain region is about 5 um.

17. The method of claim 12, wherein:
the single crystal semiconductor layer is silicon; and
the TFT is one of p-type and n-type.

18. The method of claim 12, further comprising bonding the single crystal semiconductor layer on the glass or glass-ceramic substrate such that the glass or glass ceramic substrate includes:
a first layer adjacent to the single crystal semiconductor layer with a reduced positive ion concentration having substantially no modifier positive ions; and
a second layer adjacent to the first layer with an enhanced positive ion concentration of modifier positive ions.

19. The method of claim 18, wherein the second layer includes at least one alkaline earth modifier ion from the first layer of the glass or glass ceramic substrate.

20. The method of claim 18, wherein relative degrees to which the modifier positive ions are absent from the first layer and the modifier positive ions exist in the second layer are such that substantially no ion re-migration from the glass or glass ceramic substrate into the single crystal semiconductor layer may occur.
